(19) United States
(12) Patent Application Publication
(10) Pub. No.: US 2014/0015107 A1
(43) Pub. Date: Jan. 16, 2014

(54) METHOD TO IMPROVE WITHIN WAFER UNIFORMITY OF CMP PROCESS

(71) Applicants: Ching-Kun Chen, Hsinchu City (TW); Chun-Fu Chen, Taipei City (TW); Chin-Ta Su, Yunlin Country (TW)

(72) Inventors: Ching-Kun Chen, Hsinchu City (TW); Chun-Fu Chen, Taipei City (TW); Chin-Ta Su, Yunlin Country (TW)

(73) Assignee: MACRONIX INTERNATIONAL CO., LTD., Hsin-chu (TW)

(21) Appl. No.: 13/547,333

(22) Filed: Jul. 12, 2012

(51) Int. Cl. B24B 49/14; H01L 29/06; H01L 21/306; B24B 49/02; B24D 3/00

(52) U.S. Cl. 257/618; 451/1; 451/7; 451/461; 438/8; 257/E21.23; 257/E29.005

(57) ABSTRACT

Closed loop control may be used to improve uniformity of within wafer uniformity using chemical mechanical planarization. For example, closed loop control may be used to determine a control profile for a chemical mechanical planarization process to more uniformly and consistently achieve the desired extent of variation of within wafer uniformity of a semiconductor wafer.

### TECHNOLOGICAL FIELD

Embodiments of the present invention relate generally to chemical mechanical polishing (CMP) processes and, more particularly, to the use of measurement techniques and closed loop control (CLC) to improve within wafer uniformity.

### BACKGROUND

Since the advent of computers, there has been a steady drive toward producing smaller and more capable electronic devices, such as computing devices, communication devices and memory devices. To reduce the size of such devices, while maintaining or improving their respective capabilities, the size of components within the devices must be reduced. Several of the components within electronic devices are made from semiconductor materials, which in some cases are provided via a structure called a semiconductor wafer.

In recent years, there have been numerous advances related to enhancing the ability of semiconductor device manufacturers to produce semiconductor devices with reduced dimensions. Reductions in semiconductor device dimensions may provide higher densities and improve performance of integrated circuits. In many electronic devices that employ integrated circuits, the integrated circuits may include millions of discrete elements such as transistors, resistors and capacitors that are built in close proximity to each other on a single wafer. In some cases, the close proximity of these elements can create undesirable effects such as parasitic capacitance or other performance degrading conditions. Accordingly, electrical isolation of elements on a common substrate in semiconductor devices is an important part of the fabrication process.

Additionally, performance of the device may be affected by the extent of variations that exist from the center to the edge of the device. Within wafer uniformity is a parameter that identifies the extent of variations in a wafer. Large variations in within wafer uniformity caused by any number of variables in the fabrication process. For example, non-planar surface formation resulting from inconsistencies in layer thickness caused by parameters in deposition or other processing techniques, over-filling of channels, surface void spaces, etc.

Chemical mechanical planarization combines both chemical action and mechanical forces to remove metal and dielectric overlayers, for example, to remove excess oxide in shallow trench isolation steps and to reduce topography across a dielectric region. Components required for chemical mechanical planarization typically include a chemically reactive liquid medium in the form of a slurry and a polishing surface to provide the mechanical control required to approach planarity. The slurry may contain abrasive inorganic particles to enhance the reactivity and mechanical activity of the process. Typically, for dielectric polishing, the surface may be softened by the chemical action of the slurry, and then removed by the action of the particles.

In a chemical mechanical planarization process, a wafer is affixed to a wafer carrier using back pressure. The wafer is polished by contacting it with a rotating polishing pad. The slurry is applied as the platen rotates. The number of wafers that may be simultaneously processed varies depending upon the design of the platen.

The chemical mechanical planarization process removes excess material from a dielectric layer to achieve a desired critical dimension of, for example, contact or vias at each layer or to remove excess fill material in trenches. An integrated circuit typically has multiple dielectric layers whereby chemical mechanical planarization or polishing follows the metallization step for each of the layers. However, due to variations in existing processing techniques, precise control of within wafer uniformity may be difficult to achieve using conventional processing techniques.

For example, variations due to the mechanical nature of a chemical mechanical planarization process, within wafer uniformity may be difficult to achieve. For example, polishing rates at the center of the wafer may differ from those experienced close to the edge of the wafer. There is a need in the art for an improved system, process or method to achieve improved within wafer uniformity and consistency in critical dimensions while maintaining or even increasing processing throughput.

Because of the inconsistencies that may be experience in within wafer uniformity resulting from post-processing a batch of wafers, it is typical to preprocess wafers and adjust the processing parameters as needed to achieve desired target values. However, this is imprecise, time-consuming, and results in lost production. Additionally, while wafers processed earlier in the batch may achieve a desired within wafer uniformity, variations in processing later in this batch of wafers are not accommodated and may be subjected to off-specification processing. There is a need in the art for more precise control of the extent of polishing in a chemical mechanical planarization process and improved within wafer uniformity across a batch of wafers that are processed.

As post processing becomes more commonplace, particularly as integrated circuits continue to be reduced in size, consistently maintaining within wafer uniformity increasingly becomes important. Accordingly, it may be desirable to provide an improved system, process or method for the control of within wafer uniformity, in particular, the control of within wafer uniformity in real-time as the wafer is being processed.

### BRIEF SUMMARY OF EXEMPLARY EMBODIMENTS

Embodiments of the present invention are therefore provided that may provide for improved control of a finishing tool to more uniformly achieve a desired property attribute of an integrated circuit such as a wafer.

An aspect of the invention provides a system for controlling a thickness profile of a wafer comprising a control model, a chemical mechanical planarization tool, and at least one sensor device for measuring the thickness profile of the wafer. The control model is configured to receive the thickness profile of the wafer measured by the at least one sensor device and determines a control profile for the chemical mechanical planarization tool.

In an embodiment of the invention, the control profile comprises a plurality of control variables for a polishing head of the chemical mechanical planarization tool. Pursuant to this embodiment, the plurality of control variables may include, for example, a plurality of pressures, a plurality of heat, and/or a plurality of temperatures applied to a series of points across the polishing head.

According to some embodiments of the invention, the chemical mechanical planarization tool is a metal chemical mechanical planarization tool and the thickness profile is a metal thickness profile. The metal chemical mechanical planarization tool may be, in non-limiting embodiments, either a copper or a tungsten chemical mechanical planarization tool and the thickness profile may be either a copper or a tungsten thickness profile, respectively.

An aspect of the invention provides a chemical mechanical planarization tool comprising a polishing head, the polishing head having a plurality of heat applied to a series of points across the polishing head. In an embodiment of the invention, the plurality of heat applied to the series of points is controlled to achieve a desired thickness profile of a wafer that is polished using the chemical mechanical planarization tool.

In an embodiment of the invention, the polishing head additionally comprises a plurality of pressures applied to another series of points across the polishing head, and the plurality of heat applied to the series of points and the plurality of pressures applied to the another series of points determines the desired thickness profile.

In an embodiment of the invention, the polishing head of the chemical mechanical planarization process may have a plurality of temperatures applied to the series of points and the plurality of heat is adjusted to achieve a desired temperature profile across the polishing head.

An aspect of the invention provides a method of controlling a thickness profile of a wafer including the steps of specifying a target for the thickness profile; measuring the thickness profile of the wafer; determining a control profile for a chemical mechanical planarization process using the measured thickness profile, the target, and a control model; applying the control profile to the chemical mechanical planarization process; and polishing the wafer using the chemical mechanical planarization process and the applied control profile.

In one embodiment of the invention, the method additionally comprises repeating the measuring, determining, and applying steps at periodic interval while continuing to apply the control profile to the chemical mechanical planarization process.

In one embodiment of the invention, the control profile may be a plurality of pressures applied to a series of points across a polishing head of the chemical mechanical planarization process or a plurality of heat applied to a series of points across a polishing head of the chemical mechanical planarization process.

In certain embodiments of the invention, the method of controlling the thickness profile of the wafer may also include the steps of measuring a starting thickness of the wafer and adapting the at least one control variable using the measured starting thickness and the control model.

An aspect of the invention provides a wafer for a semiconductor device fabricated by a process comprising the steps of specifying a target for the thickness profile; measuring the thickness profile of the wafer; determining a control profile for a chemical mechanical planarization process using the measured thickness profile, the target, and a control model; applying the control profile to the chemical mechanical planarization process; and polishing the wafer using the chemical mechanical planarization process and the applied control profile.

It is to be understood that the foregoing general description and the following detailed description are exemplary, and are not intended to limit the scope of the invention. These embodiments of the invention and other aspects and embodiments of the invention will become apparent upon review of the following description taken in conjunction with the accompanying drawings. The invention, though, is pointed out with particularity by the appended claims.

### BRIEF DESCRIPTION OF THE SEVERAL VIEWS OF THE DRAWING

Having thus described the invention in general terms, reference will now be made to the accompanying drawings, which are not necessarily drawn to scale, and wherein:

FIG. 1 is a graphical representation of the within wafer uniformity of a wafer following polishing using a prior art tungsten chemical mechanical planarization processing technique;

FIG. 2 illustrates a metal thickness sensor for in-situ monitoring of metal thickness distribution across a wafer according to an embodiment of the invention;

FIG. 3 illustrates a CMP polishing head having zone pressure control that may be combined with temperature control according to an embodiment of the invention;

FIG. 4A illustrates a chemical mechanical planarization head having partial thermal control according to an embodiment of the invention;

FIG. 4B illustrates a cross-sectional view of the chemical mechanical planarization head taken along the sectioning line BB′ of FIG. 4A;

FIG. 4C illustrate a heater for a CMP head N number of heaters according to an embodiment of the invention;

FIG. 4D illustrates a heater for a CMP head having a higher density of heaters towards an outer edge of the CMP head according to an embodiment of the invention;

FIG. 4E illustrates a heater for a CMP head having a higher density of heaters towards a center of the CMP head according to an embodiment of the invention;

FIG. 4F illustrates a heater for a CMP head having heaters that have been separated into parts throughout the CMP head according to an embodiment of the intention;

FIG. 4G illustrates a heater for a CMP head having heaters that have been randomly separated according to an embodiment of the invention;

FIG. 4H illustrates a heater for a CMP head having heaters with thicker elements according to an embodiment of the invention;

FIG. 5A is an illustration of a closed loop control diagram employed in an exemplary embodiment of the invention;

FIG. 5B is an illustration of a closed loop control diagram having feedforward control employed in an exemplary embodiment of the invention; and

FIG. 6 is a process flow diagram showing the steps of a method for improving within wafer uniformity by adjusting heat to achieve a desired temperature profile across a polishing head according to an exemplary embodiment of the invention.

### DETAILED DESCRIPTION

Some embodiments of the present invention will now be described more fully hereinafter with reference to the accompanying drawings, in which some, but not all embodiments of the invention are shown. Indeed, various embodiments of the invention may be embodied in many different forms and should not be construed as limited to the embodiments set forth herein; rather, these embodiments are provided so that this disclosure will satisfy applicable legal requirements.

As used in the specification and in the appended claims, the singular forms “a”, “an”, and “the” include plural referents unless the context clearly indicates otherwise. For example, reference to “a wafer” includes a plurality of such wafers.

Although specific terms are employed herein, they are used in a generic and descriptive sense only and not for purposes of limitation. All terms, including technical and scientific terms, as used herein, have the same meaning as commonly understood by one of ordinary skill in the art to which this invention belongs unless a term has been otherwise defined. It will be further understood that terms, such as those defined in commonly used dictionaries, should be interpreted as having a meaning as commonly understood by a person having ordinary skill in the art to which this invention belongs. It will be further understood that terms, such as those defined in commonly used dictionaries, should be interpreted as having a meaning that is consistent with their meaning in the context of the relevant art and the present disclosure. Such commonly used terms will not be interpreted in an idealized or overly formal sense unless the disclosure herein expressly so defines otherwise.

As used herein, “chemical mechanical planarization” (CMP) is a process for smoothing surfaces using the combination of chemical activity and mechanical forces. Chemical mechanical planarization, otherwise also known as a polishing process, may be used to further refine the finished structural features of an integrated circuit. Chemical mechanical planarization or polishing may be a hybrid process that includes other chemical reactions, such as, for example, hydrolysis or oxidation, and some form of polishing.

Chemical mechanical planarization may encompass processes that use of abrasive and/or corrosive chemical slurries such as colloidal suspensions in conjunction with a polishing pad. More specifically, a metal chemical mechanical planarization tool such as, in a non-limiting example, a tungsten chemical mechanical planarization process (W CMP) is directed specifically to post-processing treatment of integrated circuits that use a metal such as tungsten, for example, in contacts or vias for connecting transistors and interconnecting layers.

As used herein, “finishing” means performing a post-processing operation on a wafer. A finished wafer is intended to mean a wafer that has been subjected to the post-processing operation and does not necessarily mean a wafer that has completed manufacturing in all respects. In a non-limiting example, finishing means polishing a wafer to achieve a desired within wafer uniformity. The wafer may continue to undergo additional metallization and subsequent polishing operations after completion of this finishing operation on the wafer.

The inventors have conceived of and have developed systems and methodologies for control for performing closed loop control of within wafer uniformity in integrated circuits. In particular, the inventors have conceived of and developed systems and methodologies for controlling the parameters of a chemical mechanical planarization tool to achieve more consistent and less variation in within wafer uniformity of integrated circuits.

The inventors have discovered that it is possible to reduce variation in within wafer uniformity by integrating real time closed loop control techniques with the chemical mechanical planarization process for integrated circuit finishing. The systems and methods conceived by the inventors include a closed loop control system combined with methodologies to consistently achieve more uniform within wafer uniformity utilizing a chemical mechanical planarization polishing tool. Embodiments of the invention enable real-time control of within wafer uniformity by adjusting, for example, a control profile for a chemical mechanical planarization process to achieve a more desirable, accurate, and uniform thickness profile of the wafer. In certain embodiments of the invention, the chemical mechanical planarization process is a metal chemical mechanical planarization process and the thickness profile is a metal thickness profile. In certain more specific embodiments of the invention, the chemical mechanical planarization process may be a tungsten chemical mechanical planarization process and the thickness profile may be a tungsten thickness profile.

As integrated circuits become smaller, embodiments of the inventive system and inventive method enable the desired level of within wafer uniformity to be consistently met without compromising throughput. Indeed, according to certain embodiments of the inventive system and inventive method, within wafer uniformity may be consistently met while increasing device throughput. According to certain embodiments of the inventive system and inventive method, variations in within wafer uniformity were further decreased over those variations in within wafer uniformity achieved using systems and methods of the prior art.

A wafer polishing process including, for example, an abrasive trapped or abrasive mounted pad may be controlled using the inventive techniques to provide improved uniformity of within wafer uniformity. A method of controlling the polishing of a semiconductor wafer may include employing a topologically selective slurry and/or an abrasive trapped pad or abrasive mounted pad in an initial or first polishing operation and controlling, for example, the over-polishing time of a chemical mechanical planarization process in response to feedback measurements of critical dimension for polished wafers.

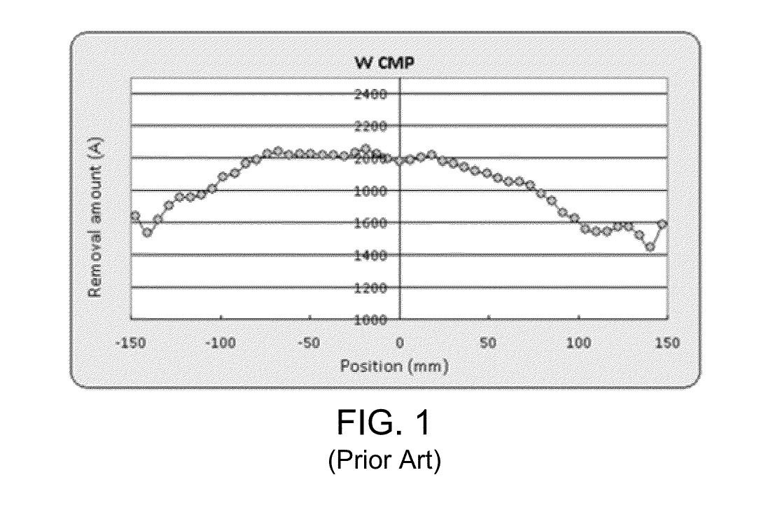

FIG. 1 is a graphical representation of the within wafer uniformity of a wafer following polishing using a prior art tungsten chemical mechanical planarization processing technique. As shown in FIG. 1 there may be as much as 600 Å or up to 50% variability in within wafer removal rates using an exemplary prior art polishing technique.

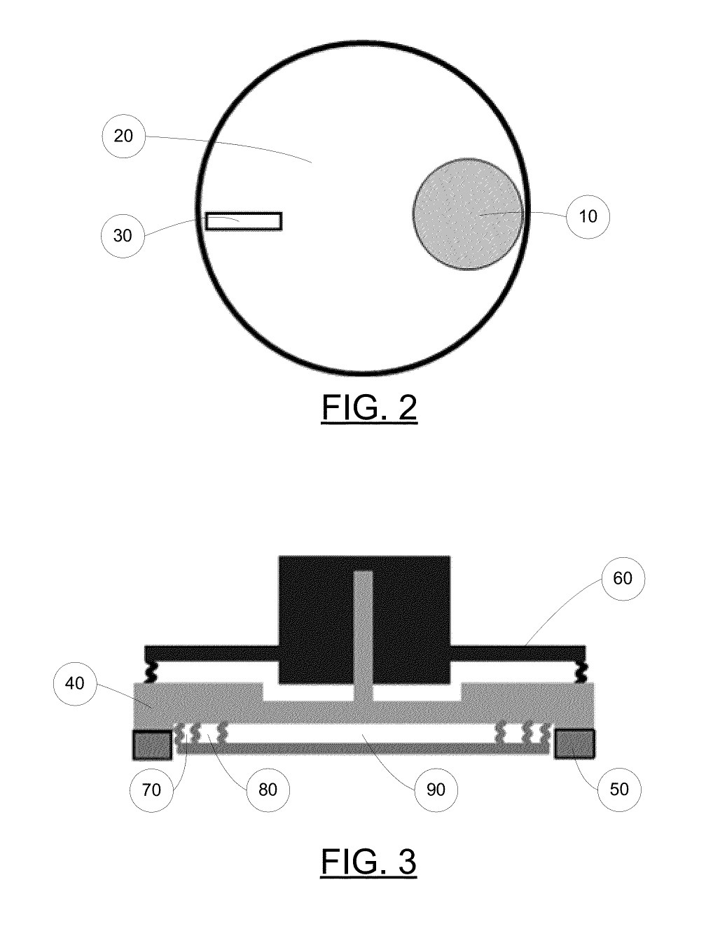

In certain embodiments of the invention, within wafer uniformity is improved by providing a thickness sensor, in particular, a metal thickness sensor, and, more particularly, a tungsten thickness sensor for measuring the distribution of thicknesses across a surface of a wafer to undergo CMP, metal CMP, and, more specifically, W CMP, processing. In certain embodiments of the invention, the thickness sensor is an in-situ measurement device. FIG. 2 illustrates a sensor for use of in-situ monitoring of thickness distribution across a wafer according to an embodiment of the invention. A wafer 10 may be polished using a CMP platen 20. According to this exemplary embodiment, the CMP platen 20 is configured with a thickness sensor 30. In certain embodiments of the invention, the CMP process is a metal CMP process and the CMP platen 20 is configured to have a thickness sensor 30 that monitors the metal thickness distribution across the surface of the wafer 10. In certain embodiments of the invention, the metal CMP process may be a W CMP process and the thickness sensor 30 monitors the tungsten thickness distribution across the surface of the wafer 10.

In certain other embodiments of the invention, the distribution of thicknesses across the surface of the wafer may be determined by use of a predictive model. In yet other embodiments of the invention, the distribution of thicknesses across the surface of the wafer may be determined by use of a predictive model and the use of a thickness sensor similar to or the same as the in-situ thickness sensor 30 of FIG. 2. In other embodiments of the invention, the distribution of thicknesses across the surface of the wafer may be determined by use of a predictive model and the use of an ex-situ thickness measurement.

In certain other embodiments of the invention, the distribution of thicknesses across the surface of the wafer may be determined by a predictive model and periodic measurements provided by an in-situ thickness sensor may be used to update the predictive model. In certain embodiments, an ex-situ thickness sensor may be used to supplement in-situ measurements provided to the model. The periodic measurements provided by the thickness sensor may be used to update the parameters of the predictive model using a predictor-corrector procedure and/or algorithm.

A thickness sensor and/or a predictive model used to determine the distribution of thicknesses across the surface of the wafer may be used by a controller or a control strategy to establish the operating parameters of a CMP process used to polish the wafer. To control the distribution of thicknesses across the wafer to achieve improved within wafer uniformity using the thickness sensor and/or the predictive model, the operating parameters of the CMP process must be capable of adjustment such that a controller may respond to variations region specific variations on the surface of the wafer.

For example, the wafer surface may be defined by variations in radial thickness such as that shown in FIG. 1. Additionally, the wafer surface may also be defined by variations in angular thickness profiles. A CMP process must be capable of controlling the platen such that these variations in both radial and angular thickness of the wafer can be controlled.

Conventionally, polishing removal rate of a CMP process has been controlled by changing rotational speed of the platen, pressure applied by the platen, the slurry flow rate, and characteristics of the slurry itself. Specifically, for a metal CMP process, temperature of the platen will affect the removal rate. For example, a higher temperature at the platen of a metal CMP process will accelerate the rate of chemical reaction between the slurry and the metal causing the polishing rate to be increased. To improve within wafer uniformity, it is necessary to use a CMP process having control parameters that can affect the extent of polishing at specific regions of the wafer, for example, utilizing a variable temperature profile in a metal CMP process.

FIG. 3 illustrates a cross sectional view of a CMP polishing head having variable pressure control across the head. A controller or control strategy using the distribution of thicknesses across the surface of a wafer measured by either a thickness sensor and/or a predictive model may adjust the operating parameters of the CMP polishing head having zone pressure control of FIG. 3. The exemplary CMP polishing head having zone pressure control of FIG. 3 is defined by, inter alia, a CMP polishing head 40 and a retaining ring 50. The pressure across the CMP polishing head 40 may be adjusted to achieve a desired profile of thicknesses across the surface of the wafer. For example, adjusting the retaining ring pressure 60 in combination with the rotational speed of the platen as well as other CMP parameters not only has the ability to affect within wafer uniformity but also wafer-to-wafer uniformity as well.

Additionally, control of the rate of polishing at specific regions may be affected by adjusting additional pressures along the CMP polishing head 40. In the exemplary embodiment illustrated in FIG. 3, a concentric zone #1 pressure 70 may be adjusted to control an edge pressure applied to the wafer, a concentric zone #2 pressure 80 may be adjusted to control a mid-band pressure applied to the wafer, and a concentric zone #3 pressure 90 may be adjusted to control a center pressure applied to the wafer. A controller using measurements provided by a thickness sensor and/or measurements provided by a predictive model may adjust the retaining ring pressure 60, the concentric zone #1 pressure 70, the concentric zone #2 pressure 80, the concentric zone #3 pressure 90, and the other CMP parameters that have conventionally been controlled to achieve an improved within wafer uniformity of thickness across the surface of the wafer. In certain embodiments of the invention, pressures of the CMP polishing head 40 at any particular zone in combination with the extent of heat applied to any particular zone as further discussed herein may be adjusted to achieve a desired finished wafer profile.

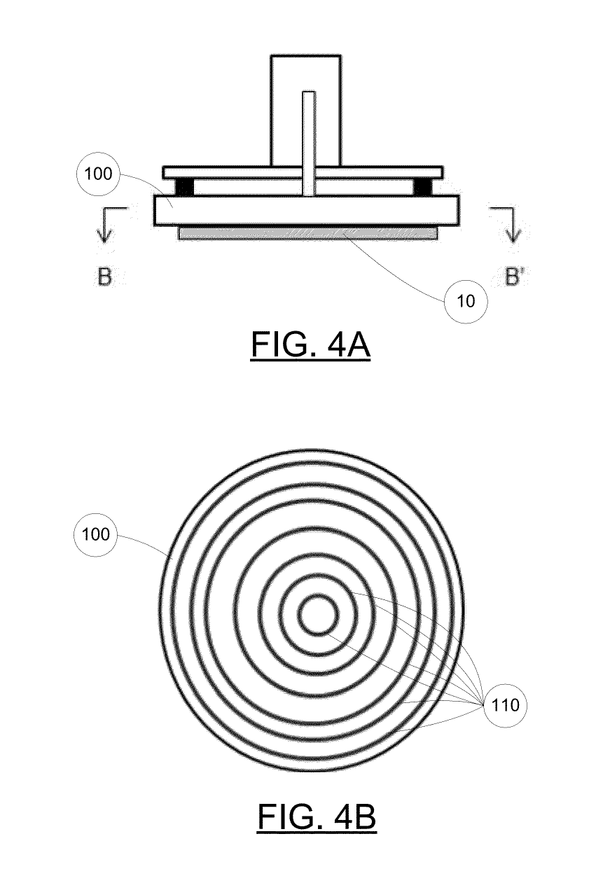

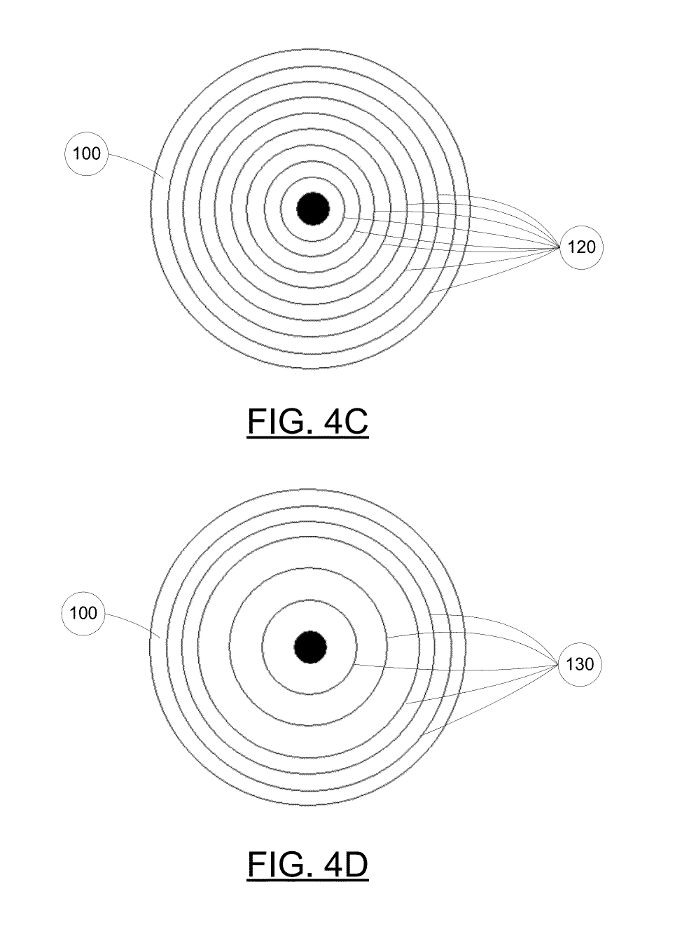

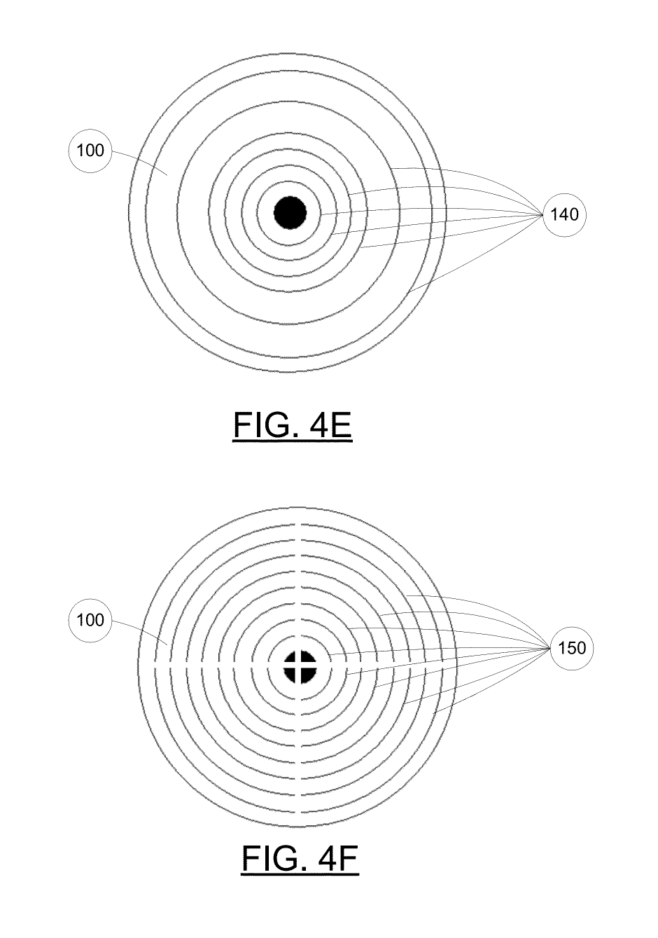

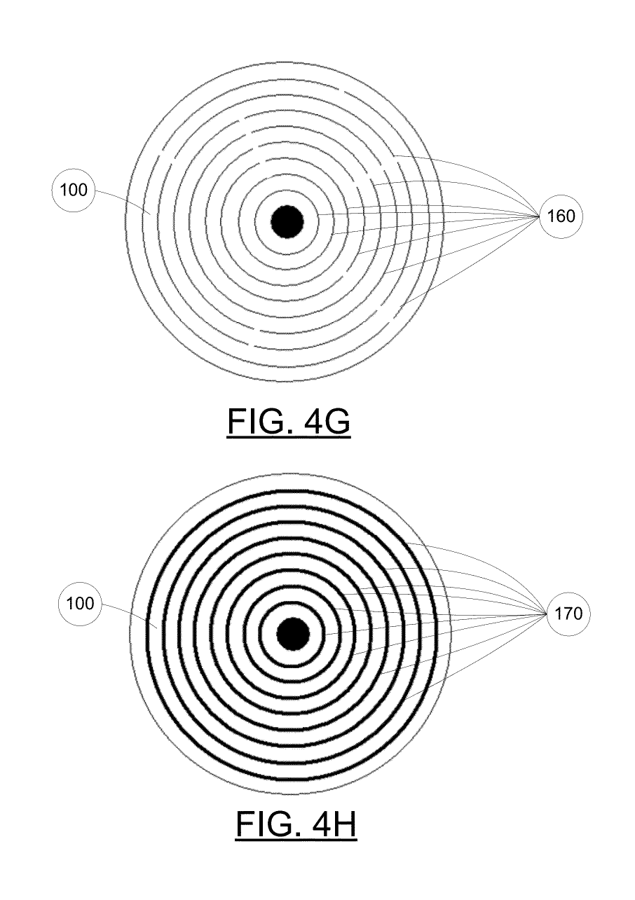

FIGS. 4A and 4B are representative of an exemplary embodiment of the invention including a CMP polishing head having variable thermal control. In certain embodiments of the invention, the CMP polishing head may have both variable pressure control and variable thermal control across the head.

In yet another embodiment of the invention, the control methodology employs the use of a device of the invention. An exemplary representation of such an inventive device is illustrated in FIG. 4A. FIG. 4A illustrates a chemical mechanical planarization head having partial thermal control. A CMP head having partial thermal control is defined by a CMP head 100 that has been configured to provide varying thermal control across the CMP head 100 as the wafer 10 is polished. FIG. 4B is a cross-sectional view of the chemical mechanical planarization head taken along the sectioning line BB′ of FIG. 4A. Heating elements 110 disposed in the CMP head 100 used to provide partial thermal control are illustrated in FIG. 4B. The heating elements 110 may be individually controlled to provide control of a variable temperature profile across the surface of the wafer 10 to achieve less variability in within wafer uniformity, i.e., to achieve improved within wafer uniformity.

In an embodiment of the invention, temperature sensors (not shown) are provided at the CMP head 100 to measure temperatures at certain regions of the wafer as it being processed. In certain embodiments of the invention, these temperature measurements may be used to establish how the CMP process should be controlled to reduce the extent of variability in the thickness profile of the wafer.

FIG. 4C is representative of an embodiment of a heater for a CMP head 100 having N number of heaters 120, where N is an integer greater than or equal to 1. FIG. 4D is representative of an embodiment of a heater for a CMP head 100 having a higher density of heaters 130 towards an outer edge of the CMP head 100. FIG. 4E is representative of an embodiment of a heater for a CMP head 100 having a higher density of heaters 140 towards a center of the CMP head 100. FIG. 4F is representative of an embodiment of a heater for a CMP head 100 where each of the heaters 150 have been separated into parts throughout the CMP head 100. While the exemplary embodiment of FIG. 4F shows symmetrical separation, other embodiments of the invention may include heaters that have been unsymmetrically separated similar to the exemplary embodiment represented by FIG. 4G where the heaters 160 have been randomly separated. FIG. 4H is representative of an embodiment of a heater for a CMP head 100 having heaters with thicker elements 170.

Any variable, as described herein, used for controlling the operation of a chemical mechanical planarization operation may be referred to herein as a “controlled variable.” As should be further understood base upon this disclosure, a series of controlled variables may be selected to achieve a desired thickness profile of the wafer. Furthermore, it should be understood that a desired thickness profile of the wafer may be achieved by setting an instantaneous target for each of these controlled variables. Furthermore, any or all of the controlled variables may not only have an instantaneous target, but may have a desired control target to be achieved over time to achieve a desired thickness profile of the wafer. The collection of variables used for controlling a CMP process and the desired instantaneous targets and the desired targets to be implemented over time may be further represented herein by a “control profile.”

An aspect of the invention provides a system, a process and a method to identify a control profile to achieve a desired thickness profile of a wafer. The finished wafer is characterized by having a reduced variability in the deviations of thickness across the wafer. Generally, the extent of deviation may be determined by dividing the difference between an average of maximum thicknesses measured across the surface by an average of the minimum thicknesses measured across the surface by the maximum thicknesses measured by the surface. This value may be multiplied by 100 to obtain the percent deviation. In certain embodiments, the systems, the processes and the methods of the invention may result in a wafer having no greater than about 15% deviation, no greater than about 10% deviation, no greater than about 5% deviation, no greater than about 3% deviation, no greater than about 2% deviation, no greater than about 1% deviation, or no greater than about 0.5% deviation in thicknesses measured across the wafer.

Many factors may affect the variability in thickness of the wafer including, but not limited to, variability in the processes leading to the unfinished wafer (e.g., mask error, hazing effects, etc.), variability in the materials used in the deposition process, differences in layout and topography, wear of the CMP polishing pad, inconsistency of the slurry used in CMP, variations in diffusional or transport rates due to inconsistencies of metallization or slurry materials, and environment effects in the production cycle, as well as other factors.

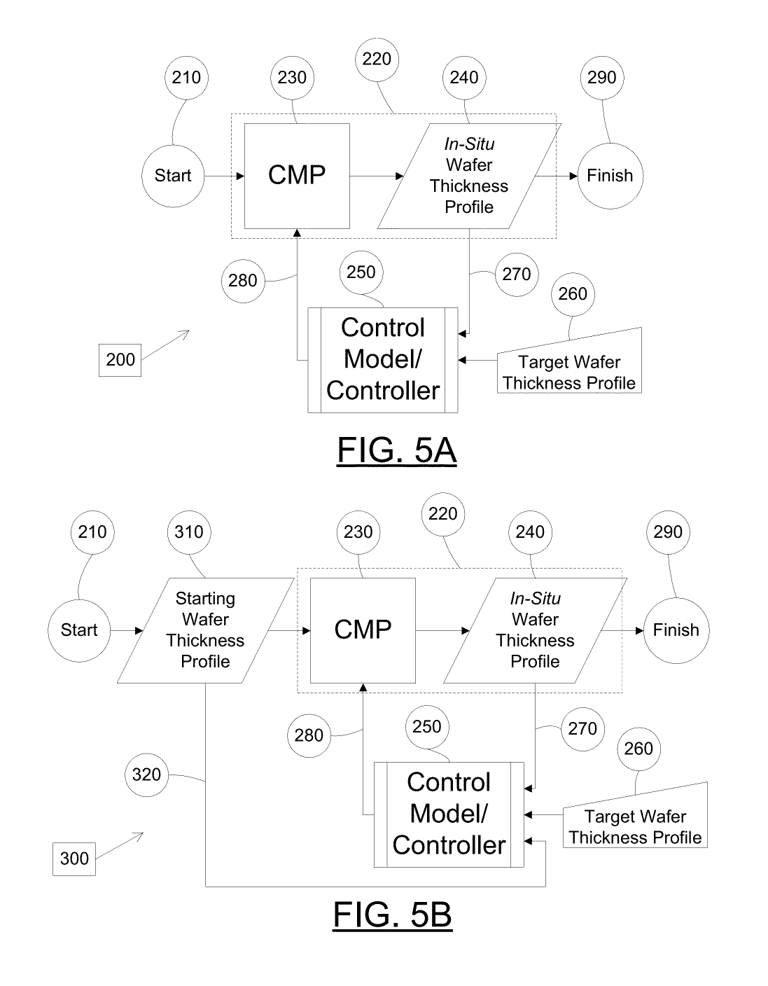

Some embodiments of the present invention may provide improvements in the within wafer uniformity of a finished wafer. In this regard, FIG. 5A provides an exemplary representation of an embodiment showing a closed loop control diagram using a control model of the invention for control of the wafer thickness, which may be extended to control of a metal thickness, more particularly, according to certain embodiments of the invention, a tungsten film thickness.

Unfinished wafers enter the process at the start 210 of the closed loop control procedure 200. The wafers are subject to processing 220 that includes a CMP process 230 and measurement of the in-situ wafer thickness profile 240 of the wafer in substantially real-time.

The thickness profile of the wafers being processed may be measured by a sensor capable of detecting in-situ the profile of the thickness of the wafer, as further described herein, and the required removal rate may be calculated for each polishing head as the wafers are being processed. The prediction of polishing time may be based upon, for example, the most recent removal rate, the thickness profile of the wafers to be processed, and the targeted extent of deviation in thickness of the polished or finished wafers. In certain embodiments of the invention, the prediction of polishing time will also consider the variation in heat applied to a series of points across the polishing head. The controller may include feedback information for the wafers as they are being polished. The controller is configured to control one or more processing variables to achieve a desired thickness profile. For example, the controller may control a plurality of heat applied to a series of points to achieve a desired thickness profile of a wafer that is polished using the chemical mechanical planarization tool.

The process control system results in improved wafer uniformity while obtaining a desired wafer profile. For example, the controller may be configured to achieve a desired wafer profile that is flat, a desired wafer profile having a thinner edge, or even a desired wafer profile having a thicker edge.

Target wafer thickness profile 260 is provided based upon the desired specifications of the wafer. A control model/controller 250 receives the target wafer thickness profile 260 and the in-situ wafer thickness profile measurement 270 for determining a desired control profile 280 to implement in the CMP process 230. The finished wafers will leave the process at finish 290 having a reduced variation in thickness profile of the wafer providing a wafer having improved within wafer uniformity.

While model-based controllers have been employed in other art segments, they have not gained widespread use in integrated circuit processing. For example, model-based controllers employing linear and/or non-linear control methods have been more common in the continuous process industries, but have not gained acceptance in the discrete time processing industries. Embodiments of the invention employ linear and/or non-linear model-based control methods.

A control model utilizes model structures and model parameters to determine the required adjustments to at least one controlled variable of a process to correct for deviations between a measured value of a variable and the desired target value for that variable. These models may include, but are not limited to, linear and/or non-linear dynamic models. The models may be, for example, single or multivariable models. The control models may be capable of adaptation to accommodate changes to any number of factors such as, for example, non-linearity in the models, model error, measurement error, etc. Model adaptation may accommodate changes in production rate or targets, for example, or may be varied depending upon response times of the various types of production equipment.

The input variables to the model may be measured or inferred and may be provided in real-time and/or discretely entered such as, for example, data that may be held in a database or manually derived. Dynamic models, in particular, are well-suited for processes and/or measurement devices having time delay or varying response times due to factors such as changes in production rate or oxide removal rate, for example.

The chemical mechanical planarization control model 250 may determine a polishing recipe providing, the desired control profile 280 to be implemented in the CMP process 230. In an embodiment of the invention, the control profile 280 provided to the CMP process 230 will allow parameters in specific regions in the CMP polishing head to be adjusted to provide more specific control of the extent of polishing that occurs at specific regions of the wafer to lead to less variability in the thickness profile of the wafer, as further described herein.

The in-situ wafer thickness profile 240 may be measured throughout the operation of the CMP process 230 using, for example, a head configured as illustrated in FIG. 2 as further described herein. The results of these at least nearly real-time profile measurements are fed back to the control model/controller 250 that will make any necessary adjustments, substantially in real-time, to the control profile 290 provided to the CMP process 230.

In certain embodiments of the invention, the CMP process will include a CMP polishing head similar that illustrated in FIG. 4A and FIG. 4B, as further described herein, to employ partial thermal control in achieving a target wafer thickness profile 260.

According to another embodiment of the invention further illustrated in FIG. 5B, a closed loop control procedure 300 is provided that substantially has the same components of the closed loop control procedure 200 of FIG. 5A except that the closed loop control model 300 further comprises feedforward compensation. The closed loop control model 300 of FIG. 5B additionally comprises a sensor for measuring, either in-situ or ex-situ, a starting wafer thickness profile 310. The starting wafer thickness profile measurement 320 is sent to and used by the control model/controller 250 as feedforward control information. This feedforward information will allow the control model/controller 250 to compensate for the measured deviations in unfinished wafers prior to undergoing polishing by making adjustments, if necessary, to the control profile 280 provide to the CMP process 230.

In addition to utilizing information concerning the thickness profile of the unfinished wafers, the control model controller 250 may also use process history information in determining the most appropriate model information to use in establishing the control profile 280 to provide to the CMP process 230 to achieve the target wafer thickness profile 260 for the finished wafers 290.

Additionally, the control model/controller 250 may be configured to receive other identifying information such as, for example, lot identification or product identification information to establish the necessary models and/or model parameters to be used in establishing the control profile 280 to be implemented by the CMP process 230. The control model/controller 250 may also be configured to receive polish tool identification information and select the appropriate control model and/or control model variables depending upon the characteristics of the CMP process 230 used to finish the wafers.

A system of the invention for finishing, preferably, for controlling a thickness profile of a wafer may comprise a control model, in particular, a chemical mechanical planarization control model, and a controller. The system of the invention may also comprise a sensor device for measuring a thickness profile of a wafer. The control model of the system may be configured as further described herein.

The sensor device, according to certain embodiments of the invention, may measure, either in-situ or ex-situ, the thickness profile of a wafer being processed. The system may comprise a feedforward sensor device for measuring a starting thickness profile of an unfinished wafer, a real-time sensor device for measuring a thickness profile of a wafer as it is being processed, or any combination thereof.

In other embodiments, the system of the invention comprises a finishing tool for a wafer. For example, in certain preferred embodiments, the wafer finishing tool is a chemical mechanical planarization tool.

The control model may receive a thickness profile of the wafer from the at least one sensor device and determine at least one control parameter, preferably, a control profile, used by the CMP tool. In certain other embodiments of the invention, the control model and controller will provide a series of control parameters, such as, for example, a control recipe or control profile to be implemented over the course of processing the wafer by the finishing tool. In other embodiments of the invention, the control model and controller will receive feedback thickness profiles of the wafer and make any adjustments the control recipe or control profile as necessary to compensate for unexpected deviations in the thickness profile of the wafer as it is being polished by the finishing tool.

In certain embodiments of the invention, the control model is configured in a control system and/or a process computer, which collects the information used by the control model that may include, but is not limited to, critical dimension of a wafer or wafers to be finished and/or a wafer or wafers that have been finished; process information for the wafer finishing tool; historical processing information collected, for example, from a database; information concerning the wafers being process such as lot identification or product information; and/or performance information for the wafer finishing tool.

As a person having ordinary skill in the art would understand given the benefit of the disclosure, the system of the invention would include other ancillary equipment, instrumentation, software, firmware, etc. as needed to make the system operational for its intended purpose.

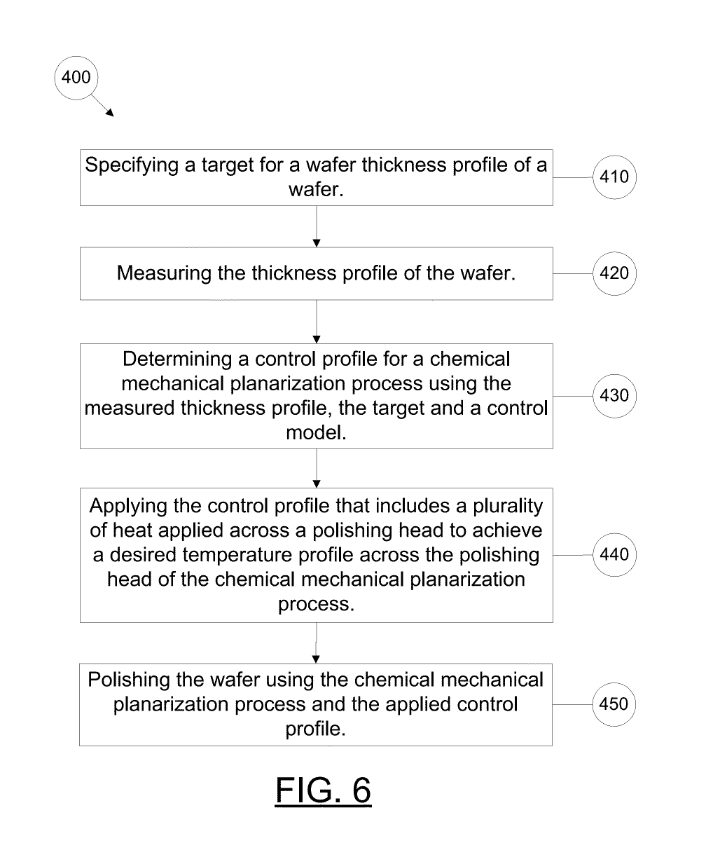

FIG. 6 is a process flow diagram showing the steps of a method for improving within wafer uniformity according to an exemplary embodiment of the invention. This exemplary method of the invention for improving within wafer uniformity 400, although not necessarily in a particular order, includes the steps of specifying a target for a thickness profile of a wafer 410, measuring the thickness profile of the wafer 420, determining a control profile for a chemical mechanical planarization process using the thickness profile, the target, and a control model 430, applying the control profile to the chemical mechanical planarization process 440, and polishing the wafer using the chemical mechanical planarization process and the applied control profile 450. According to an embodiment of the invention, the control profile may include a plurality of heat applied to a polishing head to achieve a desired temperature profile across the polishing head.

In certain embodiments of the invention, an ordered arrangement of the steps of the method may be preferred. For example, it is typically desired to provide a target for the property attribute of the wafer prior to commencing the finishing step. Furthermore, it may be desired to determine the at least one control parameter of the finishing tool just prior to the start of the finishing operation and providing updates to the at least one control parameter as the finishing operation continues.

In certain embodiments of the invention, the measuring the thickness profile 420, determining a control profile for a chemical mechanical planarization process using the measured thickness profile, the target, and a control model 430, and applying the control profile to the chemical mechanical planarization process 440 steps are repeated at periodic intervals while continuing to perform the step of polishing the wafer using the chemical mechanical planarization process 450. Without intending to be bound by the representation, such a repeated structure may be representative of a feedback control strategy.

In certain embodiments of the invention, the step of polishing the wafer using the CMP tool includes adjusting a plurality of pressures applied to a series of points across a CMP head, i.e., adjusting a pressure profile of a CMP head similar to the head that is illustrated in FIG. 3 and as further discussed herein.

In certain embodiments of the invention, the step of polishing the wafer using the CMP tool includes adjusting a plurality of heat applied to a series of points across a CMP head, i.e., adjusting a heating profile of a CMP head, for example, through heating elements or even using a measured temperature profile to further adjust heating elements, similar to that illustrated in FIG. 4A and FIG. 4B and as further discussed herein. As used herein, the latter method is defined as partial thermal control.

In certain embodiments of the invention, the step of polishing the wafer using the CMP tool includes adjusting a plurality of heat applied to a series of points across a CMP head, i.e., adjusting a heating profile of a CMP head, for example, through heating elements or even using a measured pressure profile to further adjust heating elements in combination with adjusting the plurality of heat applied to a series of points across a CMP head.

In certain embodiments of the invention, the step of polishing the wafer using the CMP tool includes adjusting a plurality of heat applied to a series of points across the polishing head and adjusting a plurality of pressures applied to another series of points across the polishing head, wherein the plurality of heat applied to the series of points and the plurality of pressures applied to the another series of points determines a desired thickness profile.

In certain embodiments of the invention, the flow rates and/or temperatures of multiple slurry addition points to the head may be controlled to achieve the variable control profile needed at the CMP head to achieve a thickness profile of a wafer having reduced variability.

In certain embodiments of the invention, the chemical mechanical planarization process or tool is a metal chemical mechanical planarization process or tool and the thickness profile is a metal thickness profile. In certain embodiments of the invention, the metal chemical mechanical planarization process or tool may a tungsten chemical mechanical planarization process or tool and the metal thickness profile may be a tungsten thickness profile.

The method of for improving within wafer uniformity 400 may additionally comprise the step of measuring a starting thickness of the wafer and adapting the at least one control variable using the control model. Without intending to be bound by the representation, such a methodology may be representative of a feedforward control strategy.

An aspect of the invention may also provide a wafer fabricated according to any of the methods of the invention.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe exemplary embodiments in the context of certain exemplary combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

What is claimed is:

1. A system for controlling a thickness profile of a wafer comprising:
a control model;
a chemical mechanical planarization tool; and
at least one sensor,
wherein the control model receives the thickness profile of the wafer measured by the at least one sensor and determines a control profile for the chemical mechanical planarization tool.

2. The system of claim 1, wherein the control profile comprises a plurality of control variables for a polishing head of the chemical mechanical planarization tool.

3. The system of claim 2, wherein the plurality of control variables comprise a plurality of heat applied to a series of points across the polishing head.

4. The system of claim 2, wherein the plurality of control variables comprise a plurality of temperatures applied to a series of points across the polishing head.

5. The system of claim 1, wherein the chemical mechanical planarization tool is a metal chemical mechanical planarization tool and the thickness profile is a metal thickness profile.

6. The system of claim 5, wherein the metal chemical mechanical planarization tool is a copper chemical mechanical planarization tool and the metal thickness profile is a copper thickness profile.

7. The system of claim 5, wherein the metal chemical mechanical planarization tool is a tungsten chemical mechanical planarization tool and the metal thickness profile is a tungsten thickness profile.

8. A chemical mechanical planarization tool comprising a polishing head having a plurality of heat applied to a series of points across the polishing head, wherein the plurality of heat applied to the series of points is controlled to achieve a desired thickness profile of a wafer that is polished using the chemical mechanical planarization tool.

9. The chemical mechanical planarization tool of claim 8 additionally comprising a plurality of temperatures applied to the series of points across the polishing head, wherein the plurality of heat applied to the series of points determines a desired temperature profile.

10. The chemical mechanical planarization tool of claim 8 additionally comprising a plurality of pressures applied to another series of points across the polishing head, wherein the plurality of heat applied to the series of points and the plurality of pressures applied to the another series of points determines the desired thickness profile.

11. A method for controlling a thickness profile of a wafer, comprising:
specifying a target for the thickness profile;
measuring the thickness profile of the wafer;
determining a control profile for a chemical mechanical planarization process using the measured thickness profile, the target, and a control model;
applying the control profile to the chemical mechanical planarization process; and
polishing the wafer using the chemical mechanical planarization process and the applied control profile.

12. The method of claim 11, additionally comprising repeating the measuring, determining, and applying steps at periodic interval while continuing to apply the control profile to the chemical mechanical planarization process.

13. The method of claim 11, wherein the control profile comprises a plurality of heat applied to a series of points across a polishing head of the chemical mechanical planarization process.

14. The method of claim 11, wherein the chemical mechanical planarization process is a metal chemical mechanical planarization process and the thickness profile is a metal thickness profile.

15. The method of claim 14, wherein the metal chemical mechanical planarization process is a tungsten chemical mechanical planarization process and the metal thickness profile is a tungsten thickness profile.

16. The method of claim 11, further comprising:
measuring a starting thickness of the wafer and
adapting the at least one control variable using the measured starting thickness and the control model.

17. A wafer for a semiconductor fabricated by a process comprising:
specifying a target for the thickness profile;
measuring the thickness profile of the wafer;
determining a control profile for a chemical mechanical planarization process using the measured thickness profile, the target, and a control model;
applying the control profile to the chemical mechanical planarization process; and
polishing the wafer using the chemical mechanical planarization process and the applied control profile.

18. The wafer of claim 17, wherein the chemical mechanical planarization process is a metal chemical mechanical planarization tool and the thickness profile is a metal thickness profile.

19. The wafer of claim 18, wherein the metal chemical mechanical planarization process is one of a copper chemical mechanical planarization tool and the metal thickness is a copper thickness profile or a tungsten chemical mechanical planarization tool and the metal thickness profile is a tungsten thickness profile.

20. The wafer of claim 17, wherein the control profile comprises a plurality of heat applied to a series of points across a polishing head of the chemical mechanical planarization process.
